(19) United States
(12) Patent Application Publication
(10) Pub. No.: US 2022/0413655 A1
(43) Pub. Date: Dec. 29, 2022

(54) TOUCH SCREEN, INITIAL VALUE SETTING METHOD THEREFOR, DISPLAY DEVICE AND ELECTRONIC DEVICE

(71) Applicant: Chipone Technology (Shenzhen) Co., Ltd., Shenzhen (CN)

(72) Inventor: Dandan SHEN, Shenzhen (CN)

(73) Assignee: Chipone Technology (Shenzhen) Co., Ltd., Shenzhen (CN)

(21) Appl. No.: 17/787,585

(22) PCT Filed: Dec. 15, 2020
(86) PCT No.: PCT/CN2020/136372

§ 371 Date: Jun. 20, 2022

(30) Foreign Application Priority Data
Dec. 18, 2019 (CN) 201911312639.2

(51) Int. Cl. G06F 3/044

(52) U.S. Cl. CPC G06F 3/0445

(57) ABSTRACT

Disclosed are a touch screen initial value setting method, a touch screen, a display apparatus, and an electronic device. The touch screen comprises: a driving electrode layer comprising a plurality, of driving electrodes; and a sensing electrode layer which is divided into a plurality of first sub-blocks and at least one basic block, wherein each of the first sub-blocks is divided into a plurality of second sub-blocks by using the basic block as a reference, the basic block and the plurality of second sub-blocks are used as sensing electrodes, and the area of the second sub-blocks is basically the same as that of the basic block. The present application improves the consistency of initial capacitance values among a plurality of sensing electrodes in the sensing electrode layer.

### CROSS-REFERENCES TO RELATED APPLICATION

This application claims the priority of the Chinese patent application filed on Dec. 18, 2019, with the application number CN201911312639.2 and the invention title “TOUCH SCREEN, INITIAL VALUE SETTING METHOD THEREFOR, DISPLAY DEVICE AND ELECTRONIC DEVICE”, the entire contents of which are incorporated in this application by reference.

### FIELD OF THE DISCLOSURE

The invention relates to the technical field of touch control, in particular to a touch screen initial value setting method, a touch screen, a display device and electronic equipment.

### DESCRIPTION OF THE RELATED ART

With the development of touch technology, touch devices are widely used in various electronic terminals. In order to meet the needs, the touch screen used in display devices or electronic devices is no longer just a regular square screen. In order to realize multi-touch control of touch screen, it is more difficult to design the induction electrode layer segmentation.

In the prior art, the situation that the initial capacitance values of each induction electrode obtained by division are inconsistent is often compensated by software. However, it is difficult to improve the consistency of the initial capacitance of induction electrodes by software compensation when the gap between the initial capacitance of induction electrodes obtained by segmentation is too large.

### SUMMARY OF THE DISCLOSURE

In view of the above problems, the present invention aims to provide a touch screen initial value setting method, a touch screen, a display device and electronic equipment, so as to improve the consistency of initial capacitance values of induction electrodes in the touch screen.

According to an aspect of the present invention, there is provided a touch screen including a driving electrode layer including a plurality of driving electrodes; And an induction electrode layer, The induction electrode layer is divided into a plurality of first sub-blocks and at least one basic block, Each of the first sub-blocks is divided into a plurality of second sub-blocks with reference to the base block. The base block and the plurality of second sub-blocks serve as induction electrodes, and the area of the second sub-block is substantially the same as that of the base block.

Preferably, the first sub-block is divided into a plurality of second sub-blocks based on the area of the first sub-block and the area of the base block.

Preferably, the area of the second sub-block located in the same first sub-block is the same.

Preferably, the shape of the base block is the same as the shape of the induction electrode layer.

Preferably, the geometric center of the base block coincides with the geometric center of the inductive electrode layer.

Preferably, at least part of the first sub-block is annular.

Preferably, the edge shape of at least part of the first sub-block is the same as the shape of the inductive electrode layer.

Preferably, the shape of the induction electrode layer is square, polygonal or circular.

Preferably, it is characterized in that the characteristic size of the base block is 2 mm to 8 mm.

According to another aspect of the present invention, there is provided a display device including the touch screen described above.

Preferably, the sensing electrodes of the touch screen are multiplexed into display electrodes.

Preferably the display device includes but is not limited to an LED display device a liquid crystal display device a micro LED display device and an OLED display device.

According to another aspect of the present invention, there is provided an electronic device comprising the touch screen described above.

Preferably, the electronic device includes, but is not limited to, a mobile phone, a computer, a tablet computer, or a wearable electronic device.

According to another aspect of the invention, a touch screen initial value setting method is provided, comprising: dividing an induction electrode layer into a plurality of first sub-blocks and at least one basic block; The first sub-block is divided into a plurality of second sub-blocks with reference to the base block, the base block and the plurality of second sub-blocks are used as induction electrodes, and the area of the second sub-block is substantially the same as that of the base block.

Preferably, the shape of the base block is the same as the shape of the induction electrode layer.

Preferably, the step of dividing the first sub-block into a plurality of second sub-blocks comprises: obtaining the number of second sub-blocks contained in the first sub-block based on the area of the first sub-block and the area of the base block; And dividing the first sub-block into a plurality of second sub-blocks with reference to the center of the base block based on the number of second sub-blocks included in the first sub-block.

Preferably, the geometric center of the base block coincides with the geometric center of the inductive electrode layer.

Preferably, at least part of the first sub-block is annular.

The invention provides a touch screen initial value setting method, a touch screen, a display device and electronic equipment, By using the induction electrode with the base block as the reference, To obtain a plurality of second sub-blocks as induction electrodes, The area of the second sub-block is basically the same as that of the basic block, so that the initial capacitance value of the second sub-block is basically the same as that of the basic block, the consistency of the initial capacitance value between the induction electrodes in the touch screen is improved, the software algorithm compensation is not needed, and the cost and resources are saved.

In some preferred embodiments, the shape of the base block is the same as the shape of the inductive electrode layer. The geometric center of the base block coincides with the geometric center of the induction electrode layer. The first sub-block surrounds the basic block in turn, and the shape of the first sub-block is concentric ring. The above arrangement between the first sub-block region and the base block region in the induction electrode layer makes the way of dividing the induction electrode layer simpler.

### BRIEF DESCRIPTION OF THE DRAWINGS

The above and other objects, features and advantages of the present invention will become more apparent from the following description of embodiments of the invention with reference to the accompanying drawings, in which:

FIG. 1 shows a schematic diagram of a sensing electrode layer of a touch screen provided according to the prior art;

FIG. 2 shows a schematic diagram of a sensing electrode layer of a touch screen provided according to an embodiment of the present invention;

FIG. 3 shows a flowchart of a method for dividing a touch screen sensing electrode layer according to an embodiment of the present invention;

FIGS. 4a-4b show schematic diagrams of a split touch screen sensing electrode layer provided in accordance with an embodiment of the present invention in various steps.

### DETAILED DESCRIPTION OF EMBODIMENTS OF THE DISCLOSURE

Various embodiments of the present invention will be described in more detail below with reference to the accompanying drawings. Throughout the various figures, like elements are denoted by the same or similar reference numerals. For the sake of clarity, various parts in the drawings are not drawn to scale.

Specific embodiments of the present invention are described in further detail below with reference to the accompanying drawings and embodiments.

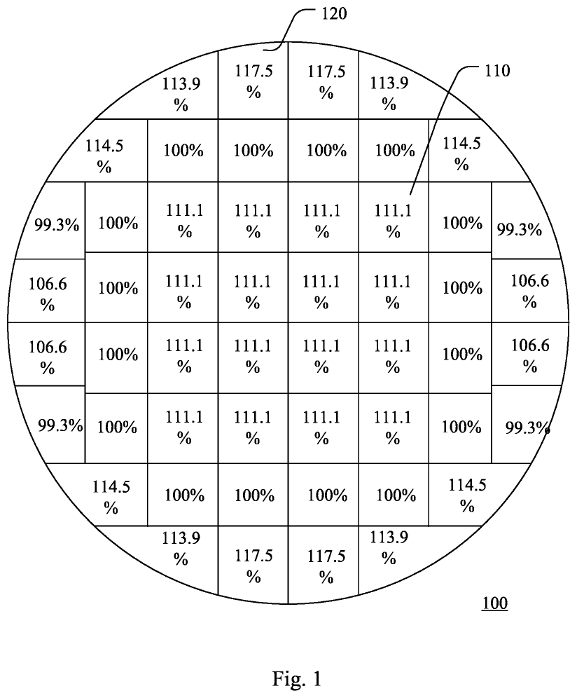

FIG. 1 shows a schematic diagram of a sensing electrode layer of a touch screen provided according to the prior art.

As shown in FIG. 1, the sensing electrode layer 100 of the touch screen is circular as an example. The inductive electrode layer 100 includes a plurality of inductive electrodes, wherein the percentage marked in each inductive electrode in the figure is a ratio of the area of each inductive electrode to a reference area, wherein the reference area is, for example, an ideal area of each inductive electrode in the inductive electrode layer 100. The area of the induction electrode is proportional to its initial capacitance.

Further, the inductive electrode layer 100 of the touch screen includes a plurality of square inductive electrodes 110 located in the middle region of the inductive electrode layer obtained by uniform division and a plurality of irregular inductive electrodes 120 located in the peripheral region of the inductive electrode layer obtained by irregular division. The area of the plurality of induction electrodes 110 in the 4*4 array in the middle region of the induction electrode layer 100 is 111.11% of the reference area, i.e. the area is uniformly distributed. The area of a plurality of square inductive electrodes 110 on the periphery of the 4*4 array in the middle region is a reference area but different from the area of the inductive electrodes in the 4*4 array in the middle region, and the difference in the initial capacitance value between the two is compensated by software. There is an area difference between each of the special-shaped induction electrodes 120 located in the peripheral area of the induction electrode layer 100, and there is also an area difference between the induction electrodes located in the middle area of the induction electrode layer 100, so that the consistency of the initial capacitance values among the induction electrodes in the induction electrode layer 100 is poor, which needs to be compensated by a software algorithm.

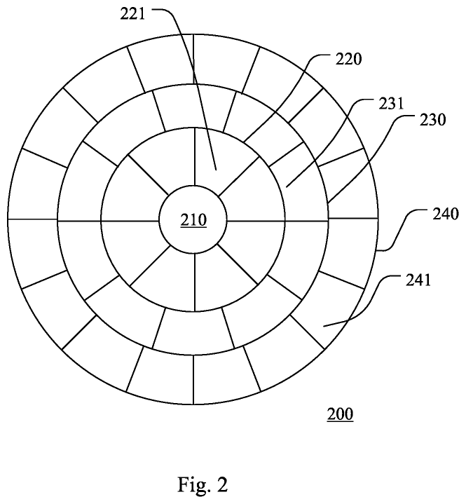

FIG. 2 shows a schematic diagram of a sensing electrode layer of a touch screen provided according to an embodiment of the present invention.

In order to meet the requirements, the shape of the sensing electrode layer of the touch screen can be square, polygonal or circular. Among them, Incell (embedded) touch screen is widely used because of its thin module thickness and low manufacturing cost. The Incell touch screen uses the principle of self-capacitance or mutual capacitance to detect the position touched by fingers. A plurality of independent capacitor arrays located on the same layer are arranged in the Incell touch screen, so as to realize multi-touch of the touch device. The touch screen in the present embodiment is described as an example of a touch screen with an incell structure but the touch screen provided by the present invention is not limited thereto and may be another touch screen with a single-layer structure for example.

As shown in FIG. 2 the sensing electrode layer 200 of the touch screen is for example circular. The inductive electrode layer 200 is divided into a plurality of first sub-block regions and at least one base block region specifically including first sub-blocks 220 230 240 and base block 210. The first sub-block 220 includes a plurality of second sub-blocks 221, the first sub-block 230 includes a plurality of second sub-blocks 231, and the first sub-block 240 includes a plurality of second sub-blocks 241. The area ratios of the second sub-blocks 221, 231 and 241 to the base block 210 are 99.5% to 100.5%, respectively. The number of the second sub-blocks 221 is related to the area of the first sub-block 220 and the area of the base block 210, the number of the second sub-blocks 231 is related to the area of the first sub-block 230 and the area of the base block 210, and the number of the second sub-blocks 241 is related to the area of the first sub-block 240 and the area of the base block 210. Preferably, a plurality of second sub-blocks located in the same first sub-block have the same area. The base block 210 serves as a reference induction electrode to obtain a plurality of second sub-blocks having the same area as the base block 210 or having a very small difference as induction electrodes, thereby improving the consistency of initial capacitance values among induction electrodes in the induction electrode layer 200.

Further the shape of the base block 210 is the same as that of the induction electrode layer 200. The geometric center of the base block 210 coincides with the geometric center of the induction electrode layer 200. The first sub-blocks 220, 230, 240 in turn surround the base block 210 and, in this embodiment, the first sub-blocks 220, 230, 240 are concentric annular in shape. The above arrangement between the first sub-block region and the base block region in the induction electrode layer 200 makes the way of dividing the induction electrode layer 200 simpler, and the consistency of the initial capacitance value of the induction electrodes between the induction electrode layers 200 is higher. The consistency of the initial capacitance values of the induction electrodes between the induction electrode layers 200 is related to the area ratio between the induction electrodes, and the accuracy of the area ratio is related to the area of each first sub-block and the area of the base block.

In the preferred embodiment, when the touch screen is a fingerprint touch screen, the feature size of the sensing electrode is set according to the finger contact size of the human body using the electronic device, that is, the feature size of the base block 210 is set to 2 mm to 8 mm.

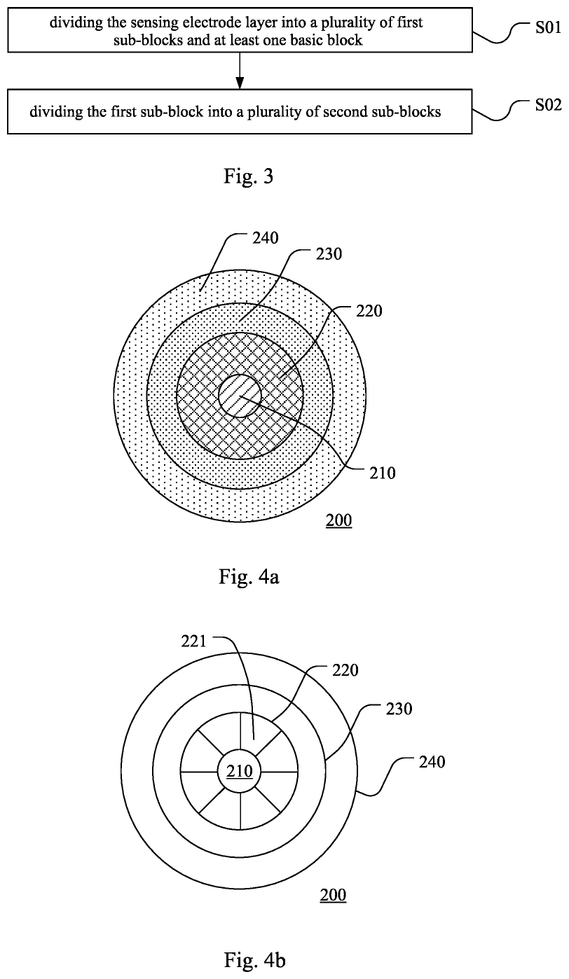

FIG. 3 shows a flowchart of a method of dividing a touch screen sensing electrode layer according to an embodiment of the present invention, and FIGS. 4a-4b show schematic diagrams of dividing a touch screen sensing electrode layer according to an embodiment of the present invention in various steps.

The invention also provides a method for setting the initial value of the touch screen. In the invention, the correlation between the area of the induction electrode and the initial capacitance value of the induction electrode is taken as the main consideration factor. Therefore, the method mainly relates to dividing the sensing electrode layer of the touch screen. The following is a detailed explanation taking the circular induction electrode layer as an example.

As shown in FIG. 3, the method of dividing the sensing electrode layer of the touch screen includes the following steps:

Step S01: The induction electrode layer is divided into a plurality of first sub-blocks and at least one base block. Referring to FIG. 4A the inductive electrode layer 200 is divided into first sub-blocks 220 230 240 and a base block 210. The base block 210 serves as a reference induction electrode.

Further the shape of the base block 210 and the shape of the induction electrode layer 200 are both circular and the geometrical center of the base block 210 coincides with the geometrical center of the induction electrode layer 200. The first sub-blocks 220, 230, 240 surround the base block 210 in turn. In this embodiment, the shape of the first sub-blocks 220, 230, 240 is concentric rings, wherein the radii of the four obtained circles from the center of the circle are a, b, c and d in turn.

In an alternative embodiment, the shape of the induction electrode layer 200 may be a polygon, a square, etc., and the shape of the corresponding base block 210 may be a polygon, a square, etc., while the first sub-block is arranged at one time around the base block and has a concentric ring shape, the edge shape of which is the same as the shape of the induction electrode layer 200.

Step S02: The first sub-block is divided into a plurality of second sub-blocks. Referring to FIG. 4B, the number of second sub-blocks included in the first sub-block is obtained based on the area of each first sub-block and the area of the base block 210, and then the first sub-block is divided into a plurality of second sub-blocks based on the number of second sub-blocks included in the first sub-block with reference to the center of the base block 210. The base block 210 and the second sub-block serve as induction electrodes, and the ratio of the area of the second sub-block to the area of the base block 210 is 99.5% to 100.5% so that the ratio of the initial capacitance value of the second sub-block to the initial capacitance value of the base block 210 is 99.5% to 100.5%.

Further the first sub-block 210 is divided into a plurality of second sub-blocks 221 and the first sub-blocks 220 230 240 are divided into a plurality of corresponding second sub-blocks in turn. Further the induction electrode layer 200 as shown in FIG. 2 is obtained.

Specifically, the following is one of the implementation methods of dividing the sensing electrode layer. The area of the base block 210 is S1=πa², the area of the first sub-block 220 is S2=πb²−πa², the area of the first sub-block 230 is S3=πc²−πb², and the area of the first sub-block 240 is S3=πc²−πb². The area is S4=πd²−πc². The first sub-block 220 is equally divided into m parts, so that S2/m=S1, the first sub-block 230 is equally divided into n parts, so that S3/n=S1, the first sub-block 240 is equally divided is q copies, so that S4/q=S1. Since m, n, and q are all the actual numbers of the second sub-blocks to be divided as sensing electrodes, they need to be integers. To sum up, the relationship between the radius of each first sub-block and the basic block and the number of divisions of the second sub-block can be obtained, that is, b=a\sqrt{m+1}, c=\sqrt{na²+b²}, d=\sqrt{qa²+c²}.

Preferably the radius of the base block 210 as one induction electrode is set according to the finger contact size of the human body using the electronic device for example the radius a of the base block 210 is 5 mm. The inner circle is not divided, and the area of the base block 210 is S1=78. 53982. And when m, n, q are too small, there are only a few recognition areas in the first sub-block of the ring, and its sensing accuracy is poor.

In the present embodiment, the first sub-block 220 is divided into eight second sub-blocks 221 as induction electrodes so that M=8, so that B=15 mm is obtained, and the area of the first sub-block 220 is S2=78. 53982. When n=10, that is, 10 second sub-blocks 231 are divided in the first sub-block 230 to serve as induction electrodes, c=21. 8 mm can be obtained, and the area of the first sub-block 230 is S3=78. 62532. If Q=16, that is, 16 second sub-blocks 241 are divided in the first sub-block 240 as induction electrodes, D=29.6 mm can be obtained; Further, the area of the first sub-block 240 is S4=78. 72052. In this embodiment, when the area of S1=S2 is 100%, the area of S3 is 100.1%, and the area of S4 is 100.2%, that is, the ratio between the areas of the induction electrodes in this embodiment tends to 100%, and the consistency of the initial capacitance values of the induction electrodes in the induction electrode layer 200 is high, so that no software algorithm is needed to compensate, and the cost and resources are saved. In an alternative embodiment, the values of M, N and Q can also be adjusted according to actual requirements to achieve the required accuracy.

The invention also provides a display device, which comprises the touch screen provided above, and the induction electrode of the touch screen in the display device can be multiplexed as a display electrode. The display device includes, but is not limited to, an LED display device, a liquid crystal display device, a micro LED display device, and an OLED display device.

The application also includes an electronic device including the touch screen provided above. The electronic device includes but is not limited to mobile phones, computers, tablet computers and wearable electronic devices.

In accordance with embodiments of the invention such as described above these embodiments are not exhaustively described in all detail nor are the invention limited to the specific embodiments described. Obviously, according to the above description, many modifications and changes can be made. These embodiments are selected and specifically described in this specification in order to better explain the principles and practical applications of the invention, thereby enabling those skilled in the art to make good use of the invention and modifications based on the invention. The invention is limited only by the claims and their full scope and equivalents.

1. A touch screen comprising:
a driving electrode layer, comprising a plurality of driving electrodes; and
a sensing electrode layer, the sensing electrode layer is divided into a plurality of first sub-blocks and at least one basic block, each of the first sub-blocks is divided into a plurality of second sub-blocks with reference to the basic block, the basic block and the plurality of second sub-blocks serve as sensing electrodes, and the area of the second sub-block is substantially the same as that of the basic block.

2. The touch screen according to claim 1, wherein the first sub-block is divided into a plurality of second sub-blocks based on the area of the first sub-block and the area of the basic block.

3. The touch screen according to claim 2, wherein the area of the second sub-block located in the same first sub-block is the same.

4. The touch screen according to claim 1, wherein the shape of the basic block and the shape of the sensing electrode layer are the same.

5. The touch screen of claim 4, wherein a geometric center of the basic block coincides with a geometric center of the sensing electrode layer.

6. The touch screen of claim 4, wherein at least part of the first sub-block is annular.

7. The touch screen of claim 6, wherein at least a portion of the first sub-block has an edge shape that is identical to the shape of the sensing electrode layer.

8. The touch screen according to claim 1, wherein the shape of the sensing electrode layer is square, polygonal or circular.

9. The touch screen initial value setting method according to claim 8, wherein the characteristic size of the basic block is 2 mm to 8 mm.

10-12. (canceled)

13. An electronic device comprising:
the touch screen according to claim 1.

14. The electronic device of claim 13, wherein the electronic device includes, but is not limited to, a mobile phone, a computer, a tablet computer, and a wearable electronic device.

15. A method for setting an initial value of a touch screen, comprising:
dividing the sensing electrode layer into a plurality of first sub-blocks and at least one basic block; and
dividing the first sub-block into a plurality of second sub-blocks with reference to the basic block, the basic block and the plurality of second sub-blocks are used as sensing electrodes, and the area of the second sub-block is substantially the same as that of the basic block.

16. The touch screen initial value setting method according to claim 15, wherein the shape of the basic block is the same as that of the sensing electrode layer.

17. The touch screen initial value setting method according to claim 15, wherein the step of dividing the first sub-block into a plurality of second sub-blocks comprises:
obtaining the number of second sub-blocks included in the first sub-block based on the area of the first sub-block and the area of the basic block; and
dividing the first sub-block into a plurality of second sub-blocks with reference to the center of the basic block based on the number of second sub-blocks included in the first sub-block.

18. The touch screen initial value setting method according to claim 15, wherein the geometric center of the basic block coincides with the geometric center of the sensing electrode layer.

19. The touch screen initial value setting method of claim 18, wherein at least part of the first sub-block is annular.

20. The touch screen initial value setting method according to claim 19, wherein at least part of the edge shape of the first sub-block is the same as the shape of the sensing electrode layer.
